(19) United States
(12) Patent Application Publication
(10) Pub. No.: US 2026/0090463 A1
(43) Pub. Date: Mar. 26, 2026

(54) SEMICONDUCTOR DEVICE WITH MOISTURE DIFFUSIVE THROUGH GLASS VIA STRUCTURE

(71) Applicant: INTERNATIONAL BUSINESS MACHINES CORPORATION, ARMONK, NY (US)

(72) Inventors: Toyohiro Aoki, Yokohama (JP); Sayuri Hada, Machida-shi (JP); Naoko Katoh, Yokohama-city (JP); Hiroyuki Mori, Yasu-shi (JP); Chinami Ishikawa, Yokohama (JP); Risa Miyazawa, Isehara (JP)

(21) Appl. No.: 18/898,609

(22) Filed: Sep. 26, 2024

(51) Int. Cl. H01L 23/26; H01L 21/48; H01L 23/15; H01L 23/498

(52) U.S. Cl. CPC H10W 76/48; H10W 70/095; H10W 70/098; H10W 70/635; H10W 70/69; H10W 70/692

(57) ABSTRACT

A semiconductor device includes a glass interposer having a set of through glass vias (TGVs). At least one of the set of TGVs is filled with a moisture diffusive material.

### BACKGROUND

### Technical Field

The present disclosure generally relates to semiconductors, and more particularly, to semiconductors with moisture diffusive through glass via structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a glass interposer having a set of through glass vias (TGVs). At least one of the set of TGVs is filled with a moisture diffusive material.

In one embodiment, the moisture diffusive material has a moisture diffusivity of at least about 1×10⁻⁹ millimeter²/s.

In one embodiment, the moisture diffusive material includes at least one of: Cu paste, sintered cupper nanopaste, polyimide, and epoxy mold compound (EMC).

In one embodiment, at least one of the set of TGVs is a non-conductive moisture diffusive material.

In one embodiment, the non-conductive moisture diffusive material is an epoxy molding compound (EMC).

In one embodiment, at least one of the set of TGVs is a conductive moisture diffusive material.

In one embodiment, the conductive moisture diffusive material is one of: Cu paste, and sintered Cu nanopaste.

In one embodiment, at least one of the set of TGVs is a conductive non-filled via and surrounded by a moisture diffusive material.

In one embodiment, the conductive non-filled via surrounded by a moisture diffusive material includes a non-filled copper via surrounded by an epoxy molding compound (EMC).

In one embodiment, the conductive non-filled via surrounded by a moisture diffusive material includes a non-filled copper via surrounded by copper paste.

In one embodiment, the semiconductor device includes a moisture barrier solder below the set of TGVs.

According to an embodiment, a method for fabricating a semiconductor device includes forming a plurality of vertical holes in a glass interposer, forming a first set of vias by filling a first subset of holes with a first material, forming a second set vias by filling a second subset of holes with a second material, and forming redistribution layers over and under the glass interposer.

In one embodiment, the method includes establishing a connection between the glass interposer and a chip over the glass interposer, and forming a plurality of barrier-controlled collapse chip connections under the glass interposer.

In one embodiment, at least one of the first material and the second material is a moisture diffusive material.

In one embodiment, the moisture diffusive material includes at least one of: Cu paste, sintered cupper nanopaste, polyimide, and epoxy mold compound (EMC).

In one embodiment, at least one of the set of first material and the second material is a non-conductive moisture diffusive material.

In one embodiment, at least one of the first material and the second material is a conductive moisture diffusive material.

In one embodiment, at least one of the first set of vias and the second set of vias is a conductive non-filled via surrounded by a moisture diffusive material.

In one embodiment, the method includes forming moisture barrier solders below the glass interposer by at least one of: a solder jet method, and a ball drop method.

According to an embodiment, a semiconductor device includes a first set of vias vertically extended in an interposer and filled with a first material, a second set vias extended vertically in the interposer and filled with a second material, and redistribution layers over and under the interposer.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a semiconductor device, in accordance with an embodiment.

FIG. 2 illustrates a semiconductor device after fabrication of the first set of holes, in accordance with an embodiment.

FIG. 3 illustrates a semiconductor device after formation of the first set of vias, in accordance with an embodiment.

FIG. 4 illustrates a semiconductor device after fabrication of the second set of holes, in accordance with an embodiment.

FIG. 5 illustrates a semiconductor device after formation of the second set of vias, in accordance with an embodiment.

FIG. 6 illustrates a semiconductor device after formation of the redistribution layers, in accordance with an embodiment.

FIG. 7 illustrates a semiconductor device after attachment of the chip, in accordance with an embodiment.

FIG. 8 illustrates a semiconductor device after encapsulation of the chip, in accordance with an embodiment.

FIG. 9 illustrates a semiconductor device after grinding process, in accordance with an embodiment.

FIG. 10 illustrates a semiconductor device after formation of the barrier bumps, in accordance with an embodiment.

FIG. 11 illustrates a semiconductor device after the baking, in accordance with an embodiment.

FIGS. 12A-12D illustrate a semiconductor device with metal caps, in accordance with an embodiment.

FIGS. 13A-13E illustrate a semiconductor device with metal caps and solder caps, in accordance with an embodiment.

FIGS. 14A-14B illustrate a semiconductor device with polyimide structure, in accordance with an embodiment.

FIG. 15 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

High-density interconnections (HDIs) are used for linking various functional chips, including CPUs, GPUs, and high bandwidth memory (HBM), to realize high-performance computing systems. These interconnections are capable of supporting rapid data transfer and intensive processing tasks, making their design and material composition important to the overall system performance. In semiconductor packaging, particularly those employing a glass interposer, the integration of organic material layers—such as underfill and redistribution layer (RDL) dielectric—between the glass substrate and the silicon chip is a common practice. These organic layers provide mechanical support, enhancing thermal management, and improving electrical performance within the package.

One of the key challenges in such configurations involves the presence of moisture, which can be absorbed by the organic materials during various manufacturing processes. These processes include grinding, plating, cleaning, and even during the wait time between different stages of the manufacturing process. Materials like polyimide, used in the mold and RDL dielectric, are particularly susceptible to moisture uptake. The moisture issue becomes even more significant when dealing with through-glass vias (TGVs) that are filled with copper (Cu). Copper-filled vias are preferred over non-filled vias due to their superior electrical performance, enhancing signal integrity and reducing resistance within the interconnections. However, these Cu-filled vias pose a challenge in moisture management because it takes a significantly longer time to remove moisture from the underfill and RDL areas beneath the chip where these vias are located.

The prolonged presence of moisture in such areas can lead to severe issues during the reflow process, a stage where the package is subjected to high temperatures to melt or re-melt solder and other fusible materials to form electrical and mechanical bonds. Insufficient removal of moisture, particularly if the organic layers are not adequately baked prior to reflow, can lead to ‘popcorn’ type delamination. This term describes the explosive effect of moisture vaporizing within the material, causing it to expand rapidly and forcibly separate layers of the package, damaging the chip and compromising the integrity of the package.

Given the complexity of the manufacturing process, especially with the inclusion of high interconnection (HI) densities and advanced materials, the risk of moisture absorption increases. Each additional process step introduces potential exposure to environmental conditions that can contribute to the absorption of moisture, thus elevating the importance of stringent control measures, such as thorough baking protocols and careful monitoring of environmental conditions during manufacturing, to mitigate these risks and ensure the reliability and performance of the semiconductor package.

The disclosed semiconductor device addresses the above-mentioned needs by incorporating a moisture diffusive through glass via, e.g., a glass interposer, which serves as the platform for such interconnections. Glass is selected for its suitable electrical performance, providing a substrate for maintaining signal integrity across high-frequency operations. Furthermore, the surface flatness of glass is beneficial for the fabrication of fine lines. This flatness ensures a uniform deposition of materials when creating the narrow copper (Cu) lines that constitute the interconnections.

The disclosed semiconductor device can utilize a glass core substrate package that incorporates moisture diffusive (MD) TGVs. The TGV can be located under the chips before they are sealed or capped, which helps in managing internal moisture levels within the package.

The glass core substrate can be an electrical insulation, with low dielectric constant, and high thermal stability. The MD TGVs can control diffusion of the moisture that might accumulate under the chips, effectively targeting the areas where moisture control is most critical, which can prevent issues such as corrosion, electrical shorts, or material degradation, which could subsequently compromise the device's performance and reliability. The design and placement of MD TGVs ensure the MD TGVs do not weaken the structural integrity of the glass substrate while still providing effective moisture diffusion during drying process. After the drying process, the capping process uses materials and techniques that ensure a hermetic seal, preventing external moisture from entering and safeguarding against external environmental factors that could impact the device's functionality.

Accordingly, the teachings herein provide methods and systems of semiconductor device formation with moisture diffusive through glass via. The techniques described herein may be implemented in a number of ways. Example implementations are provided below with reference to the following figures.

### Example Semiconductor Device with Moisture Diffusive Through Glass Via Structure

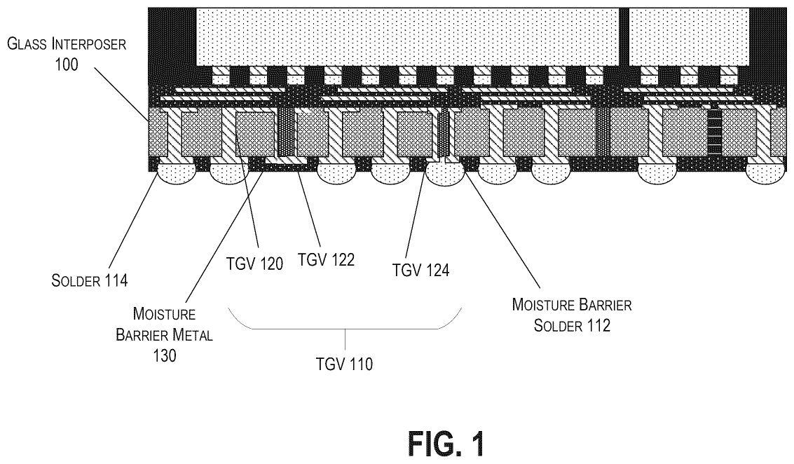

Reference now is made to FIG. 1, which is a simplified cross-section view of a semiconductor device, consistent with an illustrative embodiment. In various embodiments, the semiconductor device includes a glass interposer 100 that integrates a set of through-glass vias, TGV 110, moisture barrier layer holders 112, and one or more solders 114. The TGVs can enhance electrical connectivity and moisture management capabilities. The moisture barrier solder 112 and moisture barrier metal 130 can be positioned beneath the TGV 110 to provide protection against moisture-induced damage, ensuring the long-term integrity and functionality of the device. Then TGV 110 can include a first set of TGV 120, a second set of TGV 122, and a third set of TGV 124.

In some embodiments, the glass interposer 100 possesses a low coefficient of thermal expansion (CTE), which can match the CTE of the substrate, e.g., silicon (Si). Such a compatibility in CTE can reduce the mechanical stresses that occur due to thermal expansion and contraction during device operation and throughout the manufacturing process. Consequently, the use of glass helps in minimizing warpage and maintaining the structural integrity of the device under thermal stress.

In some embodiments, the TGV 120 within the glass interposer 100 can be filled with one or more moisture diffusive materials characterized by a moisture diffusivity rate of at least approximately 1×10 E−9 millimeter²/s, which is an order of magnitude smaller than the room temperature diffusion coefficient of polyimide. These materials can be selected for their moisture management efficacy, and can include copper paste, sintered copper nanopaste, polyimide, and epoxy mold compound (EMC). In some embodiments, TGV 120 can manage internal moisture and provide electrical pathways. The TGV 120 can further ensure optimal electrical performance while controlling moisture levels, thereby enhancing the device's operational reliability and efficiency.

The semiconductor device can utilize copper for the routing lines due to its electrical conductivity to minimize power loss and signal delay over the interconnects. The utilization of copper further complements the precision required in HDI systems, facilitating the creation of densely packed routes that are required to connect the multitude of terminals on modern chips. In addition to copper, organic dielectric materials can be employed within the interposer structure. These materials provide insulation between the copper lines, preventing electrical shorts and crosstalk between the lines. Organic dielectrics are chosen for their reliability and compatibility with the processing temperatures and chemical environments involved in semiconductor manufacturing.

The TGV 122 can be filled with an epoxy molding compound (EMC) and be configured to moisture diffusion. In some embodiments, the TGV 122 can be tailored to specifically target moisture management to protect various components from moisture-related risks without electrical interaction.

In some embodiments, TGV 124 can be non-filled vias to maintain electrical connections. The TGV 124 can be surrounded, e.g., covered, by moisture diffusive materials such as EMC or copper paste to allow the TGV 124 to remain unfilled but effectively isolated by materials that control moisture ingress and provide electrical isolation.

The moisture barrier solder 112 can be formed using several techniques, including the solder jetting process or the ball drop method. In the solder jetting process, solder is deposited onto the designated areas of the semiconductor device by ejecting small droplets of molten solder from a nozzle. This method allows for accurate placement of solder, which helps in forming moisture barriers in the semiconductor assemblies. In various embodiments, the solder only covers the areas required, which can minimize waste and reduce the risk of solder spreading to unintended regions, which could compromise the device's functionality.

Alternatively, the moisture barrier solder 112 can be formed by the ball drop method, which involves placing pre-formed solder balls directly onto the substrate in the required locations. The solder balls are then reflowed, e.g., heated until they melt, and form a continuous solder barrier. The ball drop method can allow for consistent size and placement of solder and provide reliable barriers against moisture ingress.

Overall, the integration of a glass interposer 100 with fine line copper routing and organic dielectrics in the semiconductor device can exemplify a strategic approach to enhancing the performance and reliability of high-density interconnections in high-performance computing applications. This configuration can support the electrical requirements of sophisticated computing systems and address the mechanical and thermal challenges associated with advanced semiconductor devices.

The one or more solders 114 can be formed through processes such as electroplating or the ball drop method, depending on the specific design requirements and application needs. In the electroplating process, a thin, uniform layer of solder is deposited onto the surface of the semiconductor device or its components. This is achieved by immersing the device in a plating bath that contains the solder material in an ionic form. An electric current is then applied, causing the solder ions to adhere to the desired areas of the device, forming a precise and consistent solder layer.

The incorporation of the one or more solder 114 can enhance the overall reliability and performance of the semiconductor device. The one or more solders 114 can provide mechanical bonds between the semiconductor device and its associated components, while ensuring electrical connections.

### Example Fabrication of Semiconductor Device with Moisture Diffusive Through Glass Via

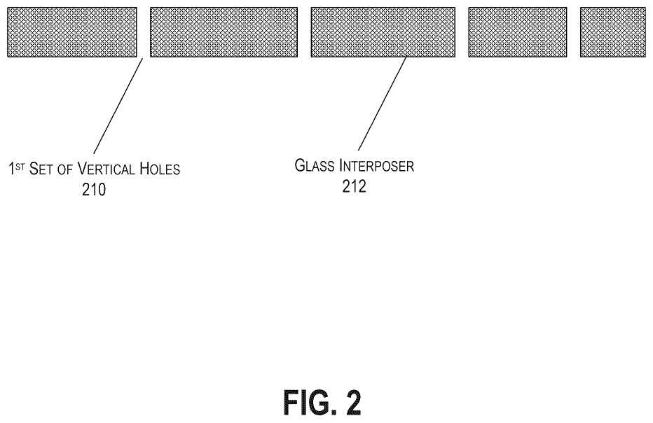

With the foregoing description of an example semiconductor device, it may be helpful to discuss an example process of manufacturing the same. To that end, FIGS. 2-11 illustrate various acts in the manufacture of a semiconductor device, consistent with illustrative embodiments.

Reference now is made to FIG. 2, which is a simplified cross-section view of a semiconductor device, after the formation of the holes. The semiconductor device can include a first set of vertical holes 210 within a glass interposer 212. These first set of vertical holes 210 can serve as the foundation for creating through-glass vias (TGVs) that facilitate electrical connectivity and other functions within the semiconductor device.

The glass interposer 212 can be a substrate used in semiconductor packaging, serving as an intermediary layer between a semiconductor chip (or multiple chips) and the underlying printed circuit board (PCB) or package substrate. In various embodiments, the function of the glass interposer 212 is to connect the dense input/output (I/O) connections of the chip(s) to the larger, less dense connections on the PCB, which enhances electrical performance and supports complex system integrations.

The glass interposer 212 can be composed of glass, a material chosen for its electrical insulation, low dielectric constant, and high thermal stability. Glass can further provide a smooth, flat surface for the fine line fabrication required in high-density interconnects. The first set of vertical holes 210 are drilled through the glass interposer 212 and filled with conductive materials, such as copper, to enable electrical connections between the different layers of the semiconductor package. The resulted TGVs can allow signals and power to pass through the interposer from the chips to the PCB.

In some embodiments, on both the top and bottom surfaces of the glass interposer 212, redistribution layers (RDLs) can be formed. The RDLs can consist of patterned metal traces that reroute the chip's I/O connections to align with the larger pitch connections on the PCB. The RDLs can bridge the gap between the fine-pitch connections of the chips and the coarser connections required by the PCB. Glass has a low coefficient of thermal expansion (CTE), which can be closely matched to that of silicon. This matching reduces mechanical stress that can occur due to thermal cycling, thereby improving the reliability of the connections between the chip and the glass interposer 212.

The glass interposer 212 can further be engineered with moisture management features, such as incorporating moisture diffusive materials in the TGVs or applying moisture barrier layers, for protecting the semiconductor device from moisture-induced damage, which can affect performance and longevity.

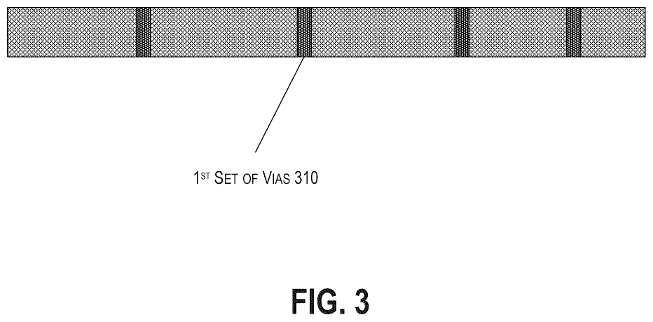

FIG. 3 illustrates a semiconductor device after the filling the first set of vertical holes with resin. In some embodiments, the first set of vertical holes are filled with different materials to create distinct sets of vias. In an embodiment, a first set of vias 310 is formed by filling one or more holes with a resin. The first set of vias 310, e.g., the resin-filled vias, can be through-glass vias (TGVs) that are filled with a resin material to achieve specific electrical, mechanical, and moisture management functions. The resin material can include epoxy resins or other organic compounds. The resin-filled vias can act as an insulating material, which helps prevent electrical shorts between different conductive pathways within the glass interposer. In some embodiments, the resin material can be engineered to have specific thermal properties that help manage the heat generated by the semiconductor device, contributing to the overall thermal management of the package.

In some embodiments, the resin-filled vias can manage moisture. As the package with glass interposers are susceptible to moisture ingress, which can lead to performance degradation or failure of the semiconductor device, the resin can create a path that accelerates removal of moisture from the inside of the package and sensitive areas of the device through the vias during drying process. In some embodiments, the resin-filled vias can contribute to the mechanical stability of the glass interposer. The resin provides structural support within the via, helping to maintain the integrity of the glass substrate, e.g., during thermal cycling or mechanical stress. This support can facilitate maintaining the reliability of the electrical connections within the interposer over the device's lifetime. In some embodiments, the resin-filled vias can be used in conjunction with other materials, such as copper, to create hybrid vias that offer both electrical conductivity and enhanced moisture management. The resin can surround a conductive core, providing insulation and moisture protection while allowing the via to carry electrical signals.

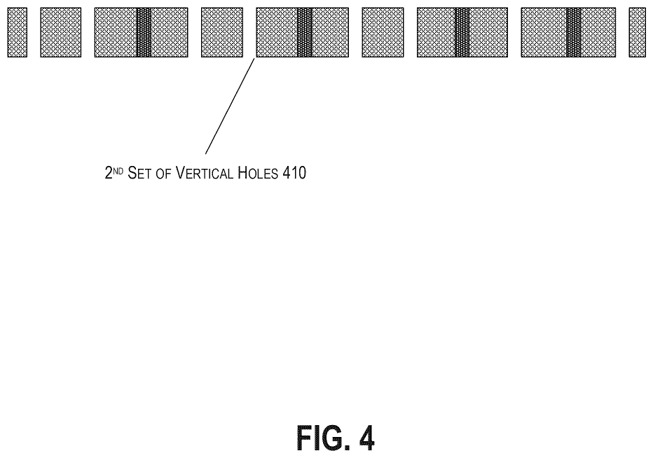

FIG. 4 illustrates a semiconductor device after the formation of the second set of holes. These first vertical holes 410 can serve as the foundation for creating through-glass vias (TGVs) that facilitate electrical connectivity and other functions within the semiconductor device.

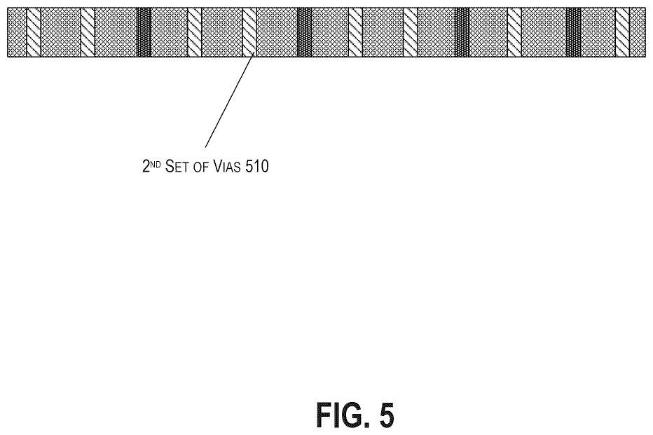

FIG. 5 illustrates a semiconductor device after the filling the second set of holes with a second material. In some embodiments, the second set of vertical holes are filled with different materials to create a second set of vias 510. The second materials are selected based on their properties, such as electrical conductivity or moisture diffusion capabilities, depending on the intended function of each via within the device. The second material can be copper.

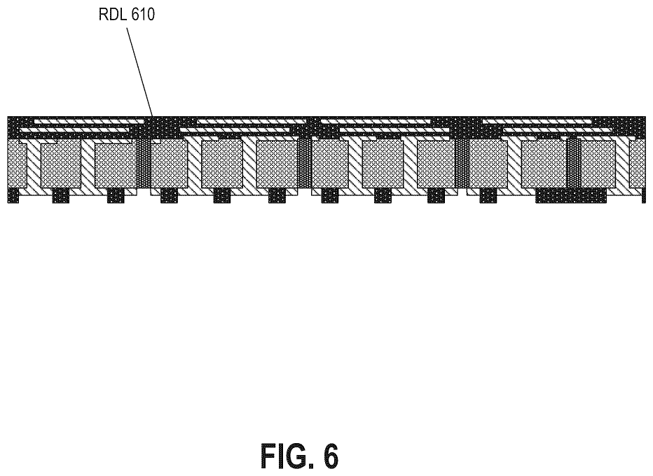

FIG. 6 illustrates a semiconductor device after the formation of redistribution layers. In some embodiments, redistribution layers, RDL 610, are formed both over and under the glass interposer 212. The RDL 610 can be used for redistributing the electrical signals and power across the semiconductor device, ensuring that connections between different components are efficiently managed.

RDL 610 can be used to modify the input/output (I/O) connections of the semiconductor device, and consists of thin metal interconnects that are patterned onto the surface of a substrate, e.g., glass interposer. The process of creating RDL 610 involves several steps. First, a thin layer of metal, e.g., copper, or thin layers of metals, e.g., titanium and copper can be deposited onto the surface of the glass interposer 212. Then, the resist coated on the thin layers of metals can be patterned using photolithography, followed by electroplating to form Cu wiring. After the photoresist removal, the thin metal layers are etched away in areas where connections are not needed, leaving behind a network of fine metal lines that form the RDL. To insulate the metal interconnects from each other and from other components, a dielectric material such as polyimide or silicon dioxide is applied. Vias, or small holes, are then created in the dielectric layer to allow connections between different layers of interconnects if multiple RDLs are used. In more embodiments, multiple RDLs are stacked, with each layer connecting different sets of I/O pads or rerouting signals in different directions. The layers are separated by additional dielectric layers, with vias providing the necessary vertical connections between layers.

The use of RDL 610 can enable higher integration density by accommodating more I/O connections on a chip, support advanced signal routing and power distribution, and improve overall electrical performance by reducing the length and resistance of interconnects. RDL 610 can further provide greater design flexibility, allowing the I/O pad layout on the chip to differ from the pad layout on the PCB or package.

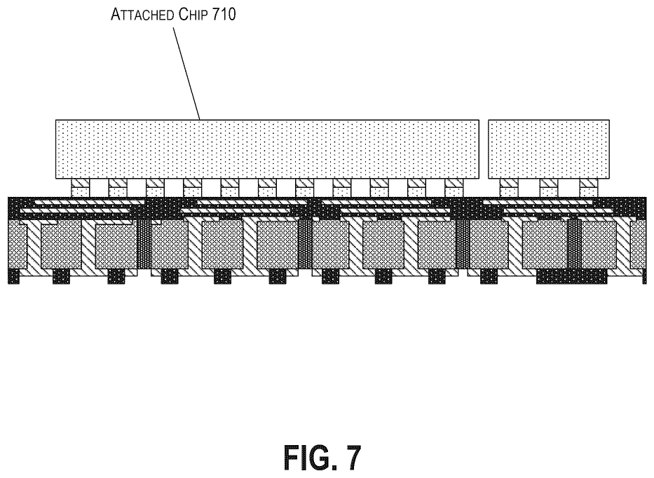

FIG. 7 illustrates a semiconductor device after the attachment of the chip to the glass interposer. In some embodiments, the connections between the glass interposer and other components, e.g., chips, are established. For instance, a connection is established between the glass interposer 212 and a chip 710 positioned above it. This connection can facilitate integrating the chip 710 into the larger system, allowing it to communicate with other components through the glass interposer 212.

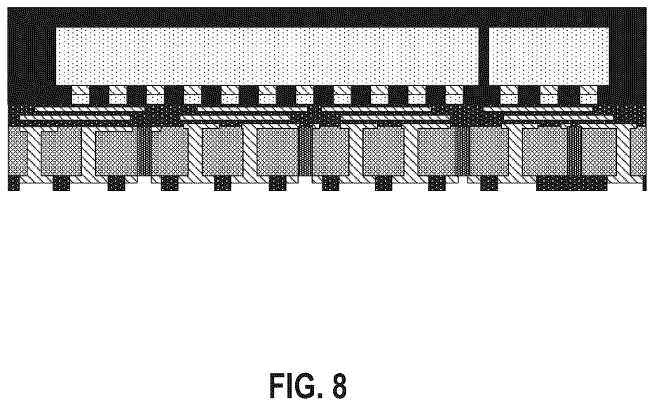

FIG. 8 illustrates a semiconductor device after the encapsulating the semiconductor device. The attached chip 710 can be encapsulated to protect the chip 710.

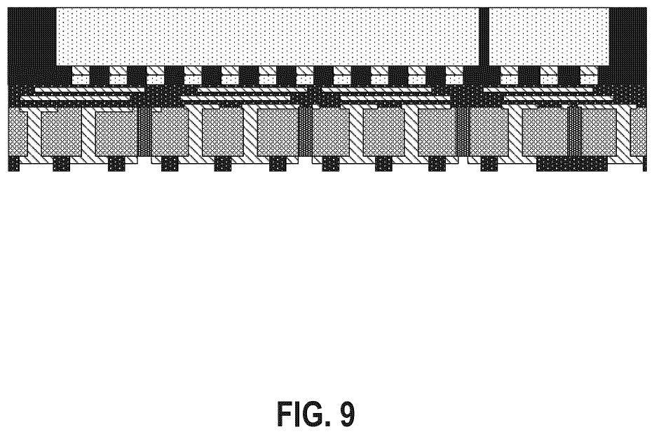

FIG. 9 illustrates a semiconductor device after the grinding. In some embodiments, the grinding and chemical mechanical planarization (CMP) are performed to achieve precise thickness control and surface smoothness on various layers of the device. Grinding can be used to reduce the thickness of semiconductor wafers or other substrate materials. This process involves mechanically removing material from the wafer's surface using an abrasive wheel or a grinding tool to rapidly and efficiently thin the wafer down to a desired thickness, making it suitable for further processing or for integration into semiconductor packages. Following grinding, CMP can be performed to achieve a high degree of surface flatness and to remove any residual surface irregularities caused by the grinding process. CMP is a hybrid process that combines both chemical and mechanical actions to polish the wafer surface. A CMP tool can use a rotating polishing pad combined with a slurry that contains both abrasive particles and chemicals designed to chemically react with the material being polished. The mechanical action of the pad, along with the chemical reaction, helps to smooth the surface and remove any remaining defects, ensuring that the wafer or the layer being polished is flat and uniform. While grinding is used for rapid material removal and achieving the initial thickness, CMP is for fine-tuning the surface and ensuring the quality needed for high-performance and reliable semiconductor devices.

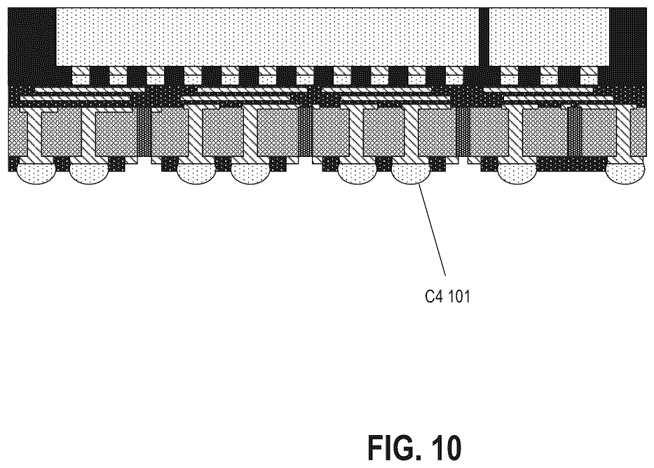

FIG. 10 illustrates a semiconductor device after the fabrication of a controlled collapse chip connections. In some embodiments, controlled collapse chip connections, C4 1010, are formed beneath the glass interposer. The C4 1010 ensures a stable and reliable interface between the chip and the interposer, providing mechanical support and electrical continuity.

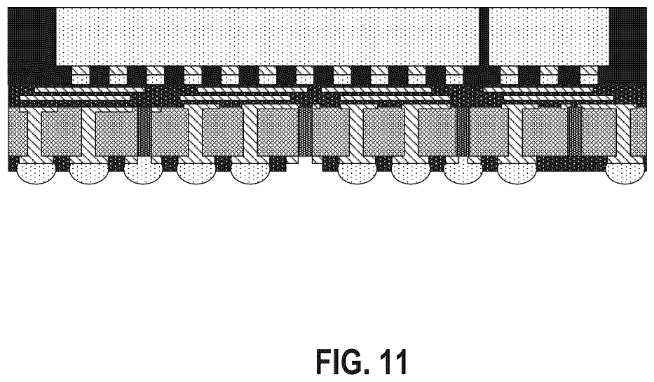

FIG. 11 illustrates a semiconductor device after the fabrication of a barrier C4 after baking. In some embodiments, the semiconductor device including the C4 is baked.

In certain embodiments, the semiconductor device incorporates materials specifically chosen for their moisture diffusive properties. At least one of the materials used to fill the vias—whether in the first or second set—is a moisture diffusive material. This material is designed to allow controlled diffusion of moisture, which facilitates maintaining the integrity and performance of the semiconductor device in environments where moisture exposure is a concern. The moisture diffusive materials that can be used include, but are not limited to, copper paste, sintered copper nanopaste, polyimide, and epoxy mold compound (EMC).

Moreover, some vias may be filled with moisture diffusive material that does not contribute to electrical connectivity. This type of via is specifically designed to manage moisture without interfering with the electrical functions of the device. On the other hand, other vias may be filled with moisture diffusive materials that do provide electrical connectivity, ensuring that the device maintains both its electrical performance and its moisture management capabilities.

In addition to filled vias, the semiconductor device further includes non-filled vias that still maintain electrical connections. These non-filled vias are surrounded by moisture diffusive materials, such as an epoxy molding compound or copper paste, creating a protective barrier that manages moisture while allowing electrical signals to pass through.

Additionally, the semiconductor device includes the moisture barrier solders below the glass interposer. These solders can be created using various techniques, including the solder jet method or the ball drop method. These moisture barrier solders can be used for preventing moisture from infiltrating the critical areas of the device, thereby preserving the functionality and reliability of the semiconductor device throughout its operational life.

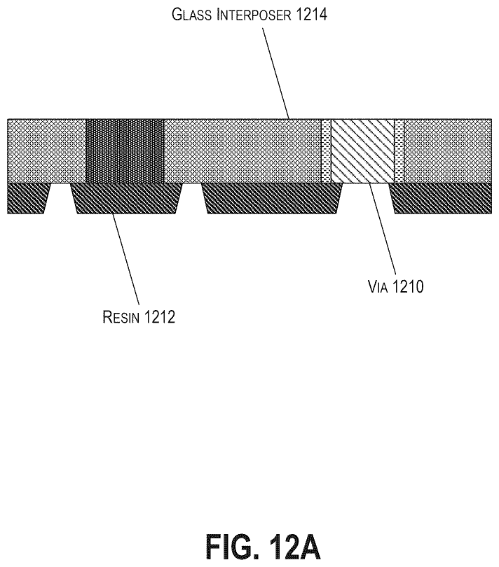

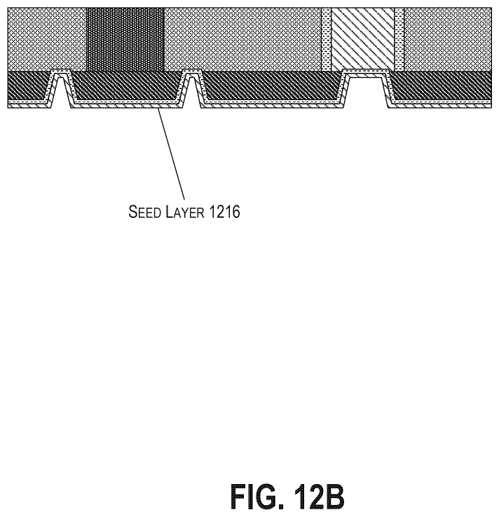

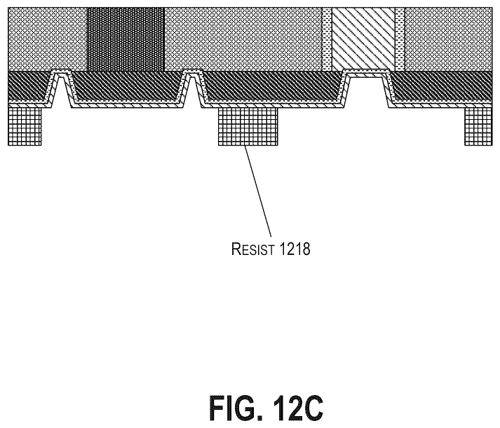

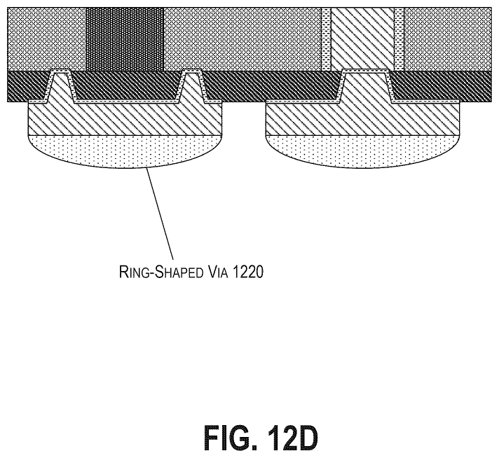

FIGS. 12A-12D illustrate formation of the semiconductor device with metal caps. Referring now to FIG. 12A, a semiconductor device is illustrated after the formation of the vias 1210, and a layer of resin 1212 formed over the glass interposer 1214.

FIG. 12B illustrates the semiconductor device after the formation of a seed layer. In some embodiments, a seed layer 1216 is formed over the layer of resin 1212. The seed layer 1216 can be a metal cap, e.g., titanium and copper barrier, for the moisture diffusive TGVs.

FIG. 12C illustrates the semiconductor device after the patterning a resist. In some embodiments, a resist layer 1218 is formed over portions of the seed layer 1216.

FIG. 12D illustrates the semiconductor device after the plating metal e.g., copper, nickel, pads and solders. In some embodiments, solders are plated over the exposed portions of the seed layer 1216. To that end, the resist layer 1218 is stripped and the seed layer 1216 is etched. Ring-shaped vias 1220 can be formed over the semiconductor device.

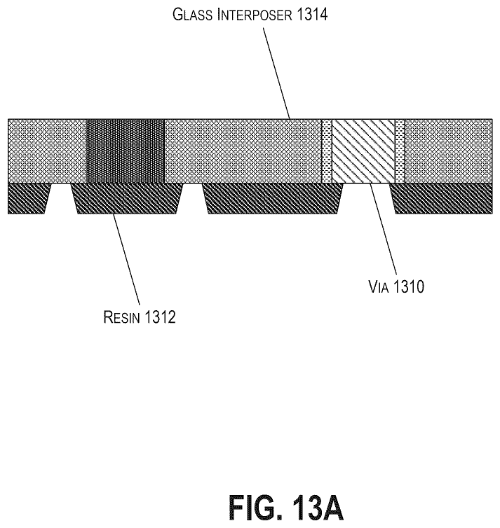

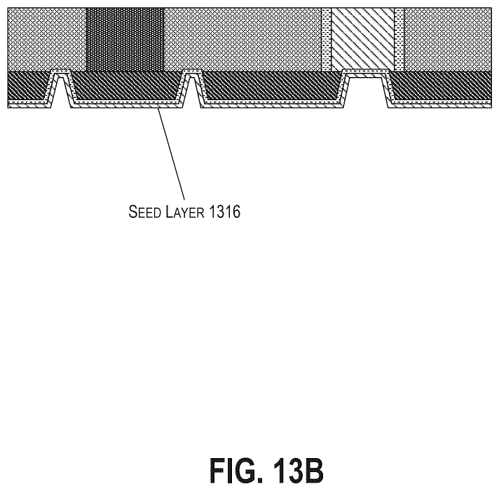

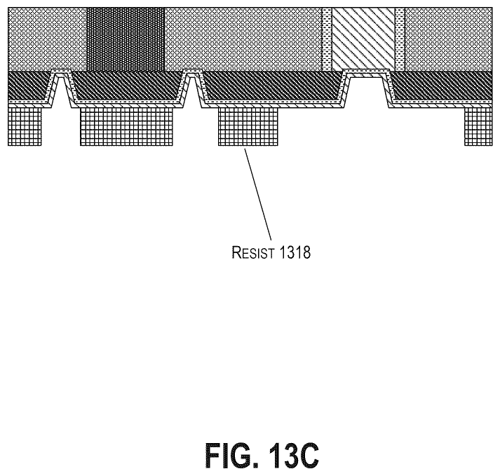

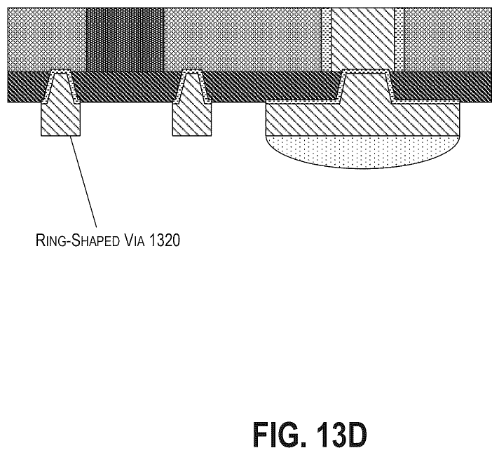

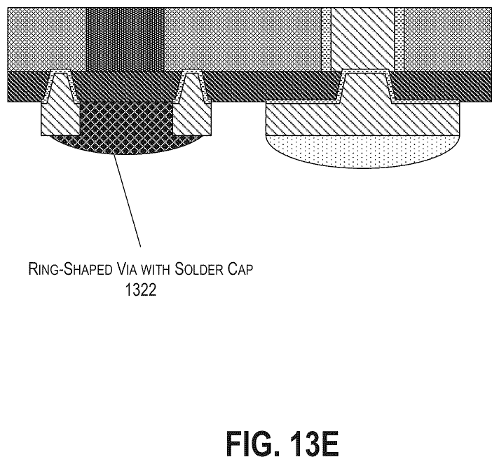

FIGS. 13A-13E illustrate formation of the semiconductor device with metal caps and solder cap. Referring now to FIG. 13A, a semiconductor device is illustrated after the formation of the vias 1310, and a layer of resin 1312 formed over the glass interposer 1314.

FIG. 13B illustrates the semiconductor device after the formation of a seed layer. In some embodiments, a seed layer 1316 is formed over the layer of resin 1312. The seed layer 1316 can be a metal cap, e.g., titanium and copper barrier, for the moisture diffusive TGVs.

FIG. 13C illustrates the semiconductor device after the patterning a resist. In some embodiments, a resist 1318 is formed over portions of the seed layer 1316.

FIG. 13D illustrates the semiconductor device after the plating copper. In some embodiments, copper is plated over the exposed portions of the seed layer 1316 to form ring-shaped via 1320. To that end, the resist 1318 is stripped and the seed layer 1316 is etched.

FIG. 13E illustrates the semiconductor device after the formation of solder caps. In some embodiments, solder caps are formed oved the copper to form ring-shaped via with solder caps 1322.

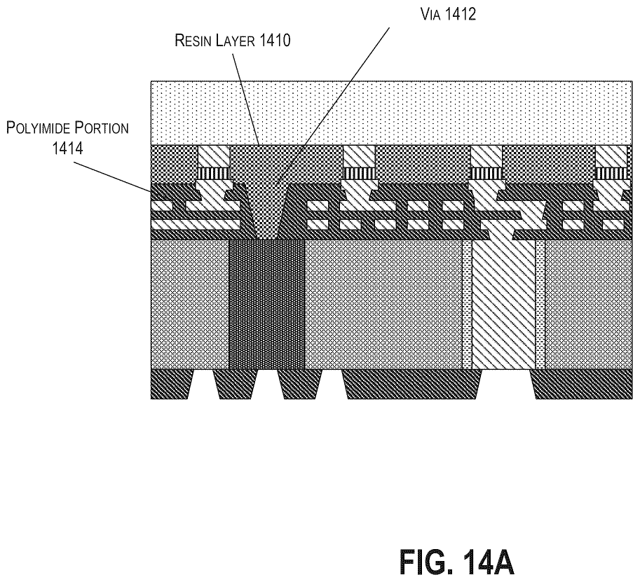

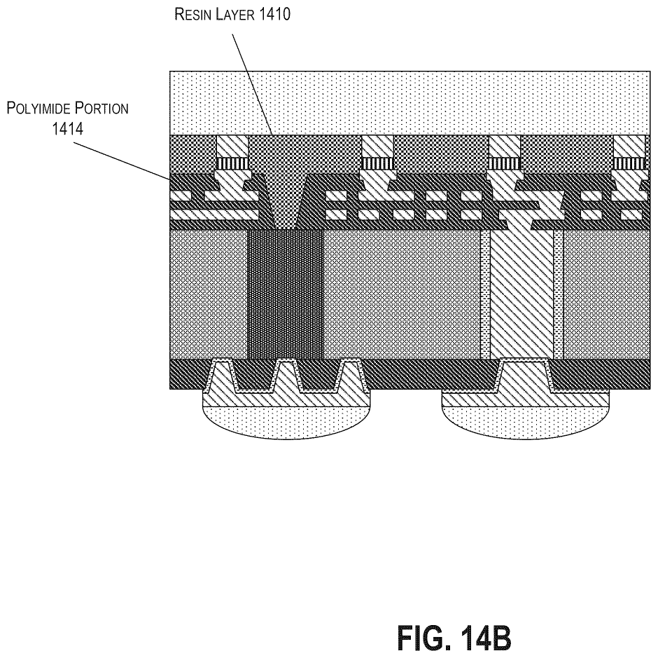

FIGS. 14A-14B illustrate a semiconductor device with polyimide structures. Referring now to FIG. 14A, a semiconductor device is illustrated with the resin layer 1410 is directly connected to the via 1412 by protruding into the polyimide portion 1414. Such a direct contact can facilitate, e.g., accelerates, moisture escape during baking. FIG. 14B illustrates the semiconductor device of FIG. 14A after forming the caps.

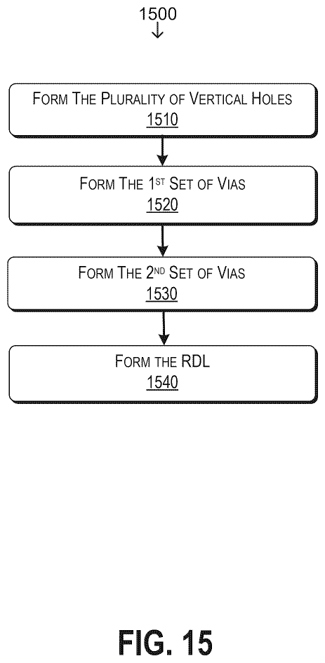

FIG. 15 illustrates a block diagram of a method 1500 for forming the semiconductor device, in accordance with some embodiments. As shown by block 1510, the plurality of vertical holes is formed in a glass interposer.

As shown by block 1520, the first set of vias are formed by filling a first subset of holes with a first material.

As shown by block 1530, the second set vias are formed by filling a second subset of holes with a second material.

As shown by block 1540, the redistribution layers are formed over and under the glass interposer.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a glass interposer having a set of through glass vias (TGVs), wherein at least one of the set of TGVs is filled with a moisture diffusive material.

2. The semiconductor device of claim 1, wherein the moisture diffusive material has a moisture diffusivity of at least about 1×10⁻⁹ millimeter²/s.

3. The semiconductor device of claim 1, wherein the moisture diffusive material includes at least one of: Cu paste, sintered cupper nanopaste, polyimide, or epoxy mold compound (EMC).

4. The semiconductor device of claim 1, wherein at least one of the set of TGVs is a non-conductive moisture diffusive material.

5. The semiconductor device of claim 4, wherein the non-conductive moisture diffusive material is an epoxy molding compound (EMC).

6. The semiconductor device of claim 1, wherein at least one of the set of TGVs is a conductive moisture diffusive material.

7. The semiconductor device of claim 6, wherein the conductive moisture diffusive material is one of: Cu paste or sintered Cu nanopaste.

8. The semiconductor device of claim 1, wherein at least one of the set of TGVs is a conductive non-filled via and surrounded by a moisture diffusive material.

9. The semiconductor device of claim 8, wherein the conductive non-filled via and surrounded by a moisture diffusive material includes a non-filled copper via surrounded by an epoxy molding compound (EMC).

10. The semiconductor device of claim 8, wherein the conductive non-filled via is surrounded by a moisture diffusive material includes a non-filled copper via surrounded by copper paste.

11. The semiconductor device of claim 1, further comprising a moisture barrier solder below the set of TGVs.

12. A method of fabricating a semiconductor device, the method comprising:
forming a plurality of vertical holes in a glass interposer;
forming a first set of vias by filling a first subset of holes with a first material;
forming a second set of vias by filling a second subset of holes with a second material; and
forming redistribution layers over and under the glass interposer.

13. The method of claim 12, further comprising:
establishing a connection between the glass interposer and a chip over the glass interposer; and
forming a plurality of barrier-controlled collapse chip connections under the glass interposer.

14. The method of claim 12, wherein at least one of the first material or the second material is a moisture diffusive material.

15. The method of claim 14, wherein the moisture diffusive material includes at least one of:
Cu paste, sintered cupper nanopaste, polyimide, or epoxy mold compound (EMC).

16. The method of claim 12, wherein at least one of the first material or the second material is a non-conductive moisture diffusive material.

17. The method of claim 12, wherein at least one of the first material and the second material is a conductive moisture diffusive material.

18. The method of claim 12, wherein at least one of the first set of vias and the second set of vias is a conductive non-filled via surrounded by a moisture diffusive material.

19. The method of claim 12, further comprising forming moisture barrier solders below the glass interposer by at least one of: a solder jet method, or a ball drop method.

20. A semiconductor device, comprising:
a first set of vias vertically extended in an interposer and filled with a first material;
a second set vias extended vertically in the interposer and filled with a second material; and
redistribution layers over and under the interposer.
